(19) United States
(12) Patent Application Publication
(10) Pub. No.: US 2013/0160372 A1
(43) Pub. Date: Jun. 27, 2013

(54) FACEPLATE FOR ELECTRONIC DEVICE

(71) Applicants: YUN-LUNG CHEN, Tu-Cheng (TW); ZHONG-HAI ZHANG, Wuhan City (CN); ZHI-LONG LI, Wuhan City (CN)

(72) Inventors: YUN-LUNG CHEN, Tu-Cheng (TW); ZHONG-HAI ZHANG, Wuhan City (CN); ZHI-LONG LI, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/593,470

(22) Filed: Aug. 23, 2012

(30) Foreign Application Priority Data
Dec. 22, 2011 (CN) 201110435042.4

(51) Int. Cl. H05K 7/00

(52) U.S. Cl. 49/386

(57) ABSTRACT

An exemplary faceplate for an electronic device includes a front plate, a cover fixed on the front plate, and an elastic member. The front plate has a pivot hole defined in a lateral side thereof the front plate, and a block and a stopper both arranged on a common inner wall of the pivot hole. The block and the stopper are spaced apart from each other and cooperatively define a receiving space therebetween. The cover includes a fixing member extending from a rear thereof at a position corresponding to the pivot hole. The elastic member includes a fixing arm pivotably engaged with the fixing member, and an abutting arm pivotable about the fixing arm. The abutting arm is retained in the receiving space when the cover is attached to the front plate, with the fixing member being received in the pivot hole.

### BACKGROUND

1. Technical Field

The present disclosure generally relates to faceplates for electronic devices, and particularly to a faceplate for an electronic device which does not employ bolts.

2. Description of Related Art

Faceplates of electronic device cases are usually configured with openings, so that users can access parts inside the electronic device case such as a hard disk drive, an optical disk drive, and so on. Further, covers are also employed in some faceplates for sheltering the openings. However, the covers are usually assembled to a front plate of the electronic device case with bolts. In particular, when the electronic device case is a computer case, bolts are used for fixing the covers on a front plate of the computer case. Thus attaching and removing the covers is a burdensome and time-consuming operation.

Therefore, it is necessary to provide a faceplate for an electronic device which can overcome the above-mentioned problems.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. In the drawings, all the views are schematic.

FIG. 1 is an exploded view of a faceplate in accordance with an exemplary embodiment of the present disclosure.

FIG. 2 is a view of the exploded faceplate of FIG. 1, seen from another aspect.

FIG. 3 is an assembled view of the faceplate of FIG. 2.

FIG. 4 is an enlarged view of a circled portion IV of FIG. 3, showing an elastic member, a fixing member and part of a front plate of the faceplate.

### DETAILED DESCRIPTION

Reference will now be made to the drawings to describe an exemplary embodiment of the present faceplate.

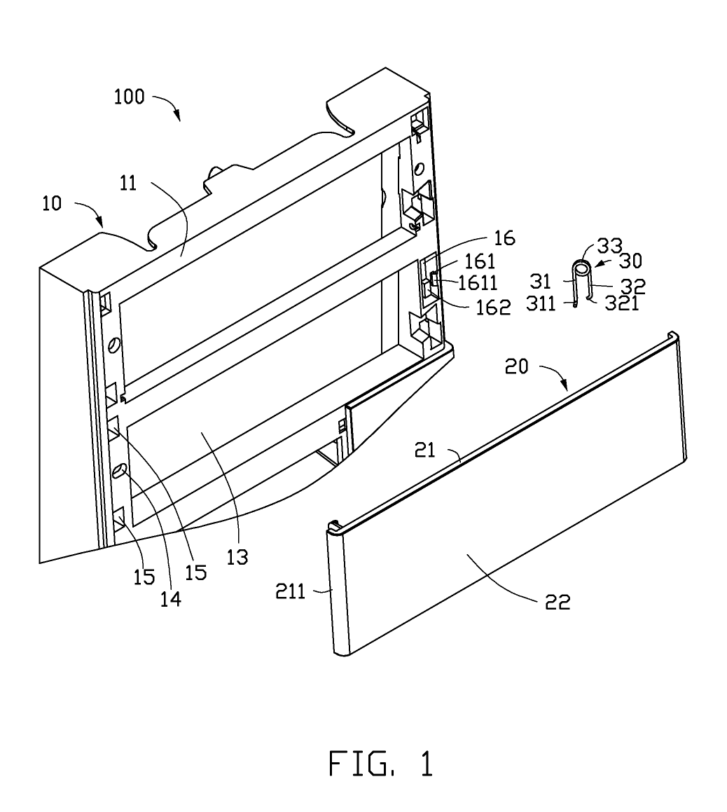

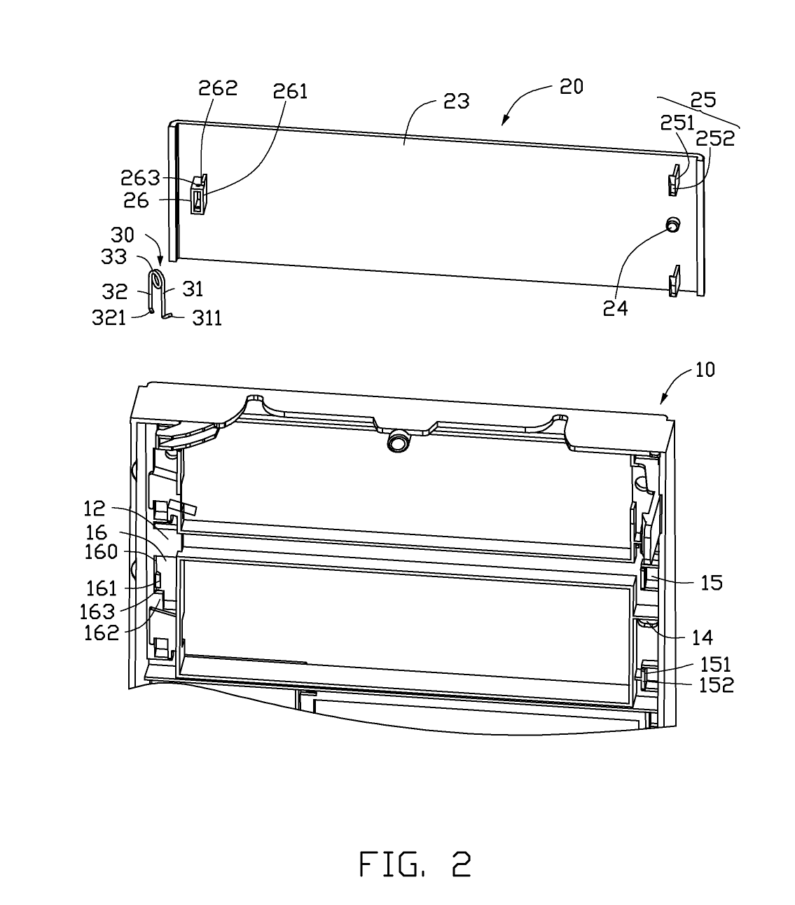

Referring to FIG. 1 and FIG. 2, a faceplate 100 for an electronic device includes a front plate 10, a cover 20 fixed on the front plate 10, and an elastic member 30. In this embodiment, the faceplate 100 is a front board of a computer case.

The front plate 10 includes a front first surface 11 and a rear second surface 12 at opposite sides thereof. The front plate 10 defines a window 13, for allowing access to, e.g., a drive located inside the electronic device. A positioning hole 14 is defined in the front plate 10 at a left lateral side of the window 13. In this embodiment, the positioning hole 14 generally has the shape of an ellipse with two opposite flattened sides. Considered another way, the positioning hole 14 generally has the shape of a running track. Two receiving holes 15 are defined in the front plate 10 adjacent to the positioning hole 14; with one of the receiving holes 15 above the positioning hole 14, and the other receiving hole 15 under the positioning hole 14. The two receiving holes 15 are symmetrical with respect to each other across the positioning hole 14. A protruding wall 151 extends rearward from the second surface 12 at an inner lateral sidewall of each receiving hole 15. That is, the protruding wall 151 is a smooth continuation of the inner lateral sidewall of the receiving hole 15, and extends along a direction away from the first surface 11. An end surface 152 is configured on a rear end of the protruding wall 151 away from the first surface 11. The end surface 152 is located rearward of the second surface 12.

A pivot hole 16 is defined in the front plate 10 at a right lateral side of the window 13. The pivot hole 16 is substantially rectangular. The pivot hole 16 has a plurality of inner sidewalls 160, a block 161, and a stopper 162.

The block 161 is located adjacent to the first surface 11. In this embodiment, the block 161 extends parallel to the first surface 11 from a right lateral one of the inner sidewalls 160 in a direction towards the positioning hole 14. That is, the block 161 extends perpendicularly from the right inner sidewall 160 towards the positioning hole 14. The block 161 has a right-angled trapezoid cross section. An oblique one of the nonparallel sides of the trapezoid is adjacent to the first surface 11. A non-oblique one of the nonparallel sides of the trapezoid is near the second surface 12 and faces away from the first surface 11. Thus, the block 161 tapers along the extending direction thereof. The block 161 includes a sloping surface 1611 adjacent to the first surface 11, the sloping surface 1611 corresponding to the oblique nonparallel side of the trapezoid.

The stopper 162 is located adjacent to the second surface 12. In this embodiment, the stopper 162 extends parallel to the second surface 12 from the right lateral inner sidewall 160 in a direction towards the positioning hole 14. That is, the stopper 162 extends perpendicularly from the right lateral inner sidewall 160 towards to the positioning hole 14. A rear surface of the stopper 162 is coplanar with the second surface 12. The stopper 162 has a cubic shape, with a rectangular cross section. The stopper 162 has a width along the extending direction thereof bigger that that of the block 161. Also, the stopper 162 is located at a level lower than a level at which the block 60 is located. Further, a top surface of the stopper 162 is substantially parallel with a bottom surface of the block 161. A receiving space 163 is defined generally between a rear surface of the block 161 and a front surface of the stopper 162.

The cover 20 is for covering the window 13 at the first surface 11 side of the front plate 10. The cover 20 includes a main body 21, and two flanges 211 extending perpendicularly rearward from opposite lateral sides of the main body 21. The main body 21 includes a front surface 22 and a rear surface 23 at opposite sides thereof. The front surface 22 is rectangular. A positioning post 24 extends rearward from a left side of the rear surface 24, corresponding to the positioning hole 14. The positioning post 24 has a cylindrical shape. Two hook members 25 extend rearward from the left side of the rear surface 23 adjacent to the positioning post 24; with one of the hook members 25 above the positioning post 24, and the other hook member 25 under the positioning post 24. Each hook member 25 includes a base portion 251 extending from the rear surface 23, and a hook 252 extending inward from a distal (rear) end of the base portion 251.

A fixing member 26 extends rearward from a right side of the rear surface 23, corresponding to the pivot hole 16. The fixing member 26 can pass through the pivot hole 16, and thereby reach and penetrate beyond the second surface 12. The fixing member 26 includes two opposite vertical first walls 261, and two opposite horizontal second walls 262. The two first walls 261 are parallel to each other. The two second walls 262 are parallel to each other. Each first wall 261 is perpendicular to both the second walls 262. The two first walls 261 and two second walls 261 cooperatively form a hollow rectangular protrusion. The two second walls 261 each define a through hole 263 therein, with the through holes 263 aligned with each other.

When the fixing member 26 is inserted into the pivot hole 16, one of the two first walls 261 abuts against a left lateral one of the inner sidewalls 160, and the other one of the two first walls 261 abuts against a left lateral side of the stopper 162. That is, the two first walls 261 of the fixing member 26 are sandwiched by the left lateral side of the stopper 162 and the left lateral inner sidewall 160 of the pivot hole 16. At this time, a bottom one of the second walls 261 maintains a distance from a bottom one of the inner sidewalls 160 of the pivot hole 16. Thus, a gap 264 is defined between the bottom second wall 261 and the bottom inner sidewall 160 of the pivot hole 16.

The elastic member 30 includes a fixing arm 31, an abutting arm 32, and a coiled portion 33 interconnecting the fixing arm 31 and the abutting arm 32. A pivoting portion 311 perpendicularly extends from a free end of the fixing arm 31, and is received in the gap 264. The abutting arm 32 is capable of rotating (pivoting) about an axis of the fixing arm 31, and thus the fixing arm 31 defines an axis of rotation of the elastic member 30. A guiding portion 321 extends from a free end of the abutting arm 32. An included angle between the guiding portion 321 and the abutting arm 32 is about 130 degrees. In this embodiment, the elastic member 30 is a spring, and the guiding portion 321 has a length smaller than that of the pivoting portion 311.

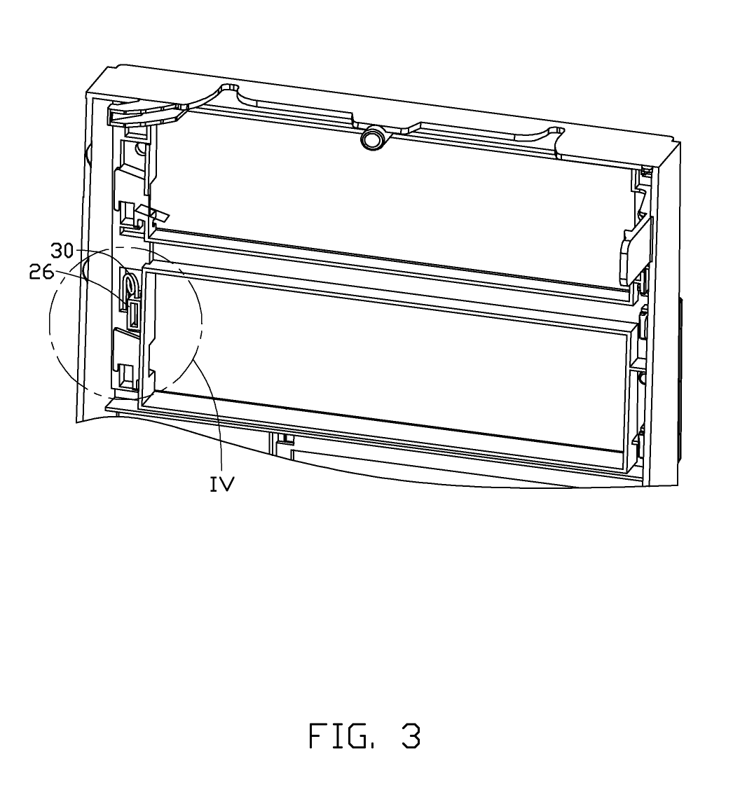

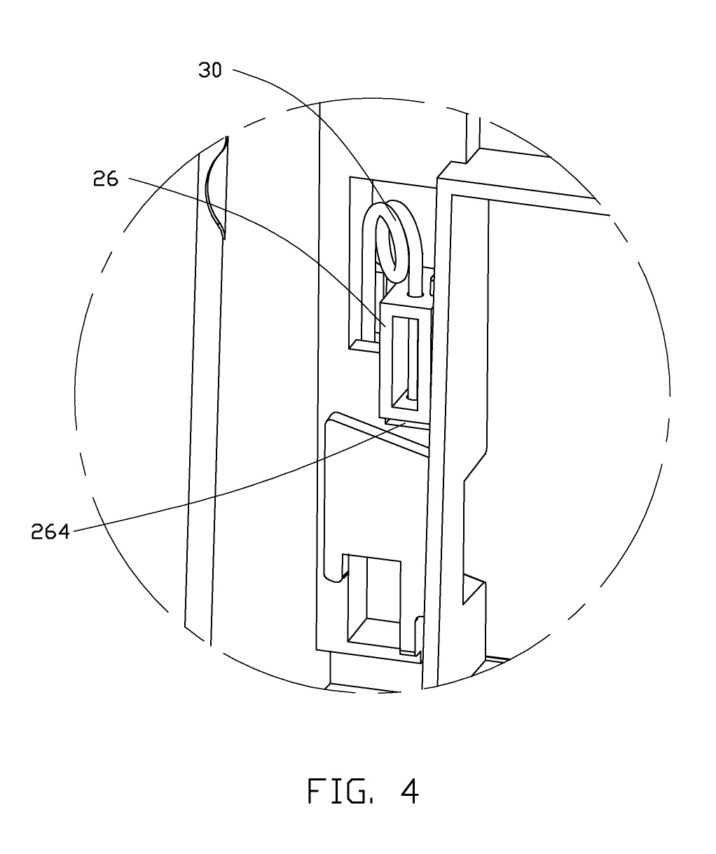

Also referring to FIG. 3 and FIG. 4, an assembling method and a disassembling method of the faceplate 100 are provided.

The assembling method of the faceplate 100 is as follows.

Firstly, the fixing arm 31 is arranged so that it is held in the through holes 263 of the second walls 262, with the pivoting portion 311 located below the bottom second wall 262. As such, the elastic member 30 is attached to the cover 20.

Secondly, a left side of the cover 20 is pushed rearward against the front plate 10, thereby making the positioning post 24 penetrate through and be movably received in the positioning hole 14, and making the hook members 25 penetrate through the corresponding receiving holes 15. Then the cover 20 is pulled rightward (more towards the pivot hole 16), thereby making the hook members 25 abut against the protruding walls 151, and making the hooks 252 move towards and catch the end surfaces 152. As such, the hook members 25 are fitted onto the protruding walls 151.

Thirdly, the right side of the cover 20 is pushed rearward against the front plate 10, thereby making the fixing member 26 extend into the pivot hole 16. During this process, initially, the abutting arm 32 of the elastic member 30 contacts the sloping surface 1611. Then during further movement of the fixing member 26 into the pivot hole 16, the abutting arm 32 is blocked by the sloping surface 1611 from moving rearward, and thereby rotates (pivots) about the axis of rotation of the elastic member 30. During such rotation, the fixing arm 31 itself correspondingly pivots about the axis of rotation of the elastic member 30; and at the same time, the pivoting portion 311 correspondingly pivots about the axis of rotation of the elastic member 30 and is received in the gap 264. After the rotation of the abutting arm 32, the abutting arm 32 is pulled rearward by the fixing arm 31 and is forced to ride along the sloping surface 1611. When the abutting arm 32 rides along the sloping surface 1611, the abutting arm 32 is elastically deformed. Once the abutting arm 32 reaches a rear edge portion of the block 161 at the rear surface of the block 161, the abutting arm 32 elastically recovers and is snappingly retained in the receiving space 163 behind the block 161. Accordingly, the whole elastic member 30, together with the fixing member 26, is received in the pivot hole 16. As such, the cover 20 is attached to the front plate 10, with the elastic member 30 being retained in the pivot hole 16.

The disassembling method of the faceplate 100 is as follows.

Firstly, the right side of the cover 20 is pulled forward away from the front plate 10, to pull the fixing member 26 out of the pivot hole 16. During this process, initially, the abutting arm 32 of the elastic member 30 is blocked by the rear surface of the block 161, and so the abutting arm 32 rotates about the axis of rotation of the elastic member 30. During such rotation, the fixing arm 31 itself correspondingly pivots about the axis of rotation of the elastic member 30; and at the same time, the pivoting portion 311 correspondingly pivots about the axis of rotation of the elastic member 30 and exits the gap 264. After the rotation of the abutting arm 32, the abutting arm 32 is still pulled by the fixing arm 31 and still blocked by the block 161, and elastically deforms. When the elastic deformation of the abutting arm 32 reaches a certain threshold, the abutting arm 32 elastically recovers and rides along the rear surface of the block 161 until the abutting arm 32 reaches the rear edge portion of the block 161; and the abutting arm 32 then rides over the rear edge portion of the block 161 and is released from the receiving space 163 and moves forward away from the sloping surface 1611 of the block 161. Accordingly, the whole elastic member 30, together with the fixing member 26, is pulled out from the pivot hole 16.

Secondly, the cover 20 is pushed leftward (more towards the positioning hole 14), thereby making the hook members 25 move away from the protruding wall 151, and causing the hooks 252 to be released from the end surfaces 152.

Thirdly, the left side of the cover 20 is pulled forward away from the front plate 10, thereby pulling the positioning post 24 out from the positioning hole 14 and bringing the hook members 25 out from the corresponding receiving holes 15. As such, the cover 20 is detached from the front plate 10.

In summary, the cover 20 of the faceplate 100 is capable of being attached to or detached from the front plate 10 by pushing and/or pulling the cover 20, whereby the elastic member 30 is engaged with or disengaged from the block 161, respectively. The attachment and detachment of the cover 20 are achieved without any need for bolts, and the whole of these processes is fast and convenient.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A faceplate for an electronic device, comprising:
a front plate comprising a central window, a pivot hole, a block and a stopper, the pivot hole being defined in a lateral side of the front plate, both the block and the stopper being arranged on an inner wall of the pivot hole, the block and the stopper spaced apart from each other and cooperatively defining a receiving space therebetween;
a cover for covering the window, the cover comprising a fixing member extending from a rear thereof at a position corresponding to the pivot hole; and
an elastic member comprising a fixing arm and an abutting arm, the fixing arm pivotably engaged with the fixing member of the cover, the abutting arm being pivotable about an axis of the fixing arm, the abutting arm being retained in the receiving space when the cover is attached to the front plate with the fixing member being received in the pivot hole.

2. The faceplate of claim 1, wherein the elastic member further comprises a pivoting portion extending from a free end of the fixing arm, and a gap is maintained between the fixing member and a bottom wall of the pivot hole when the cover is attached to the front plate, with the pivoting portion being received in the gap.

3. The faceplate of claim 1, wherein the elastic member further comprises a guiding portion extending from a free end of the abutting arm.

4. The faceplate of claim 3, wherein an included angle between the guiding portion and the abutting arm of the elastic member is approximately 130 degrees.

5. The faceplate of claim 1, wherein the block is located in a front portion of the pivot hole, and the stopper is located in another portion of the pivot hole rearward of the block.

6. The faceplate of claim 5, wherein the stopper is located at a level lower than a level at which the block is located

7. The faceplate of claim 4, wherein the block comprises a front surface obliquely oriented relative to the front plate.

8. The faceplate of claim 4, wherein the inner wall of the pivot hole is a lateral sidewall of the pivot hole, the stopper and the block both extend perpendicularly into the pivot hole from the lateral sidewall of the pivot hole, the stopper has a cubic shape, and a width of the stopper along the extending direction is bigger than a width of the block along the extending direction.

9. The faceplate of claim 1, wherein a positioning hole is defined in another lateral side of the front plate opposite to the lateral side of the front plate having the pivot hole.

10. The faceplate of claim 9, wherein the positioning hole generally has the shape of an ellipse with two opposite flattened sides.

11. The faceplate of claim 9, wherein the cover further comprises a positioning post at a rear thereof corresponding to the positioning hole, the positioning post penetrating through and being movably received in the positioning hole when the cover is attached to the front plate.

12. The faceplate of claim 11, wherein two receiving holes are defined in the other lateral side of the front plate, at top and bottom sides of the positioning hole, respectively.

13. The faceplate of claim 12, wherein the cover further comprises two hook members at a rear thereof corresponding to the receiving holes, and the hook members extend through and are engaged in the receiving holes when the cover is attached to the front plate.

14. The faceplate of claim 13, wherein a protruding wall extends rearward from an inner lateral sidewall of each of the receiving holes.

15. The faceplate of claim 14, wherein the protruding wall has a rear end surface.

16. The faceplate of claim 15, wherein each hook member comprises a base portion extending from the rear of the cover and a hook extending from a distal end of the base portion, and the base portion penetrates a corresponding one of the receiving holes and the hook catches the rear end surface of the corresponding protruding wall when the cover is attached to the front plate.

17. The faceplate of claim 12, wherein the receiving holes are symmetrical with respect to each other across the positioning hole.

18. A faceplate for an electronic device, comprising: a front plate defining a retaining space;
a cover comprising a fixing member; and
an elastic member for detachably fixing the cover to the front plate, the elastic member comprising a fixing arm and an abutting arm, the fixing arm being pivotably engaged with the fixing member of the cover, the abutting arm being pivotable about an axis of the fixing arm and snappingly retained in the retaining space when the cover is pushed against the front plate by an external force.

19. A faceplate for an electronic device, comprising:
a front plate defining a retaining space;
a cover comprising a fixing member;
an elastic member for detachably fixing the cover to the front plate, the elastic member comprising a fixing arm and an abutting arm, and the fixing arm being pivotably engaged with the fixing member of the cover, and the abutting arm being pivotable about an axis of the fixing arm;
wherein when the cover is fixed to the front plate, the abutting arm forwardly rotates about the fixing arm and elastically deforms and then elastically rebounds to be retained in the retaining space; and
when the cover is detached from the front plate, the abutting arm backward rotates about the fixing arm and elastically deforms and then elastically rebounds to be released from the retaining space.

20. The faceplate of claim 19, wherein the front plate comprises a block and a stopper spaced apart from each other and cooperatively defining the retaining space therebetween.
